(19) United States
(12) Patent Application Publication
(10) Pub. No.: US 2026/0212933 A1
(43) Pub. Date: Jul. 23, 2026

(54) CHARGE TRAPPING NOR FLASH MEMORY FOR STACKED MEMORY ARCHITECTURES

(71) Applicant: Micron Technology, Inc., Boise, ID (US)

(72) Inventors: Innocenzo Tortorelli, Cernusco Sul Naviglio (IT); Agostino Pirovano, Milan (IT); Lorenzo Fratin, Buccinasco (IT); Fabio Pellizzer, Boise, ID (US)

(21) Appl. No.: 19/435,316

(22) Filed: Dec. 29, 2025

Related U.S. Application Data
(60) Provisional application No. 63/747,803, filed on Jan. 21, 2025.

(51) Int. Cl. G11C 16/26; G11C 16/04; G11C 16/10

(52) U.S. Cl. CPC G11C 16/26; G11C 16/0466; G11C 16/102

(57) ABSTRACT

Methods, systems, and devices for charge trapping not-OR (NOR) flash memory for stacked memory architectures are described. A memory device may include one or more three-dimensional (3D) charge trapping NOR flash memory dies in a stack of memory dies. In some examples, the stack of memory dies may also include one or more volatile memory dies, while in other examples the stack of memory dies may primarily include charge trapping NOR memory dies. The stack of memory dies may also include a logic die configured to access each of the memory dies of the stack using one or more vias, channels, or other components associated with the stack. In some examples, the logic die may access the memory dies of the stack in response to an access command received from a graphics processing unit (GPU) or other processing circuitry of the memory device.

### CROSS REFERENCE

The present Application for Patent claims priority to U.S. Patent Application No. 63/747,803 by Tortorelli et al., entitled “CHARGE TRAPPING NOR FLASH MEMORY FOR STACKED MEMORY ARCHITECTURES,” filed January 21, 2025, which is assigned to the assignee hereof, and which is expressly incorporated by reference in its entirety herein.

### TECHNICAL FIELD

The following relates to one or more systems for memory, including charge trapping NOT-OR (NOR) flash memory for stacked memory architectures.

### BACKGROUND

Memory devices are used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored by the memory cell. To store information, a memory device may write (e.g., program, set, assign) states to the memory cells. To access stored information, a memory device may read (e.g., sense, detect, retrieve, determine) states from the memory cells.

### BRIEF DESCRIPTION OF THE DRAWINGS

FIG. 1 shows an example of a memory device that supports charge trapping NOT-OR (NOR) flash memory for stacked memory architectures in accordance with examples as disclosed herein.

FIG. 2 shows an example of a system that supports charge trapping NOR flash memory for stacked memory architectures in accordance with examples as disclosed herein.

FIG. 3 shows examples of memory die architectures that support charge trapping NOR flash memory for stacked memory architectures in accordance with examples as disclosed herein.

FIG. 4 shows a block diagram of a memory system that supports charge trapping NOR flash memory for stacked memory architectures in accordance with examples as disclosed herein.

FIG. 5 shows a flowchart illustrating a method or methods that support charge trapping NOR flash memory for stacked memory architectures in accordance with examples as disclosed herein.

### DETAILED DESCRIPTION

Some memory devices may be utilized for artificial intelligence (AI) applications, which may involve increased read accesses and be associated with various latency metrics. Additionally, such AI applications may involve storing a relatively large quantity of data within the memory device. In such cases, however, read latencies associated with some memory devices may not satisfy the latency metrics for AI applications. For example, some AI applications may include large numbers of read operations in quick succession. Alternatively, some memory devices may not have sufficient memory density (e.g., sufficient storage capacity) to store the increased quantity of data for AI applications (e.g., within a certain form factor or price point), may not be cost effective, or both. For example, dynamic random access memory (DRAM) devices, such as high bandwidth memory (HBM) stacks (e.g., or other three-dimensional (3D) stacked DRAM memory devices) may be associated with read performances that satisfy the various latency metrics for AI applications, however, such DRAM devices may be associated with an increased cost and have a relatively lower memory density (e.g., reduced storage capacity) as compared to other devices. Thus, memory solutions that provide for a higher memory density, while providing increased read performance at a lower cost may be desired.

To increase memory density and access operation performance at a low cost, 3D charge trapping NOT-OR (NOR) flash memory dies may be implemented in memory die stacks (e.g., an HBM stack). For example, a memory system may include one or more NOR memory dies in a stack of memory dies. In some examples, the stack of memory dies may also include one or more volatile memory dies (e.g., dies including DRAM), while in other examples the stack of memory dies may primarily include the NOR memory dies. The stack of memory dies may also include a logic die configured to access each of the memory dies of the stack using one or more vias, channels, or other components associated with the stack. In some examples, the logic die may access the memory dies of the stack in response to an access command received from a graphics processing unit (GPU) or other processing circuitry of the memory device.

The memory system may use the NOR memory dies as part of AI inference operations. For example, the logic die may write AI model parameters to the NOR memory dies. In response to one or more access commands, the logic die may read the AI model parameters from the NOR memory dies and transmit the AI model parameters to the processing circuitry, which may use the AI model parameters to perform one or more AI inference operations.

Use of the NOR memory dies may increase performance of AI models by increasing memory capacity of the memory system without decreasing bandwidth, by decreasing power usage of the memory system, and by decreasing latency of the memory system (e.g., relative to using primarily volatile memory dies).

In addition to applicability in memory systems as described herein, techniques for charge trapping NOR flash memory for stacked memory architectures may be generally implemented to improve the performance of various electronic devices and systems (including artificial intelligence (AI) applications, augmented reality (AR) applications, virtual reality (VR) applications, and gaming). Some electronic device applications, including high-performance applications such as AI, AR, VR, and gaming, may be associated with relatively high processing requirements to satisfy user expectations. As such, increasing processing capabilities of the electronic devices by decreasing response times, improving power consumption, reducing complexity, increasing data throughput or access speeds, decreasing communication times, or increasing memory capacity or density, among other performance indicators, may improve user experience or appeal. Implementing the techniques described herein may improve the performance of electronic devices by improving memory access speeds, which may decrease processing or latency times, improve response times, or otherwise improve user experience, among other benefits.

Features of the disclosure are illustrated and described in the context of systems and architectures. Features of the disclosure are further illustrated and described in the context of block diagrams and flowcharts.

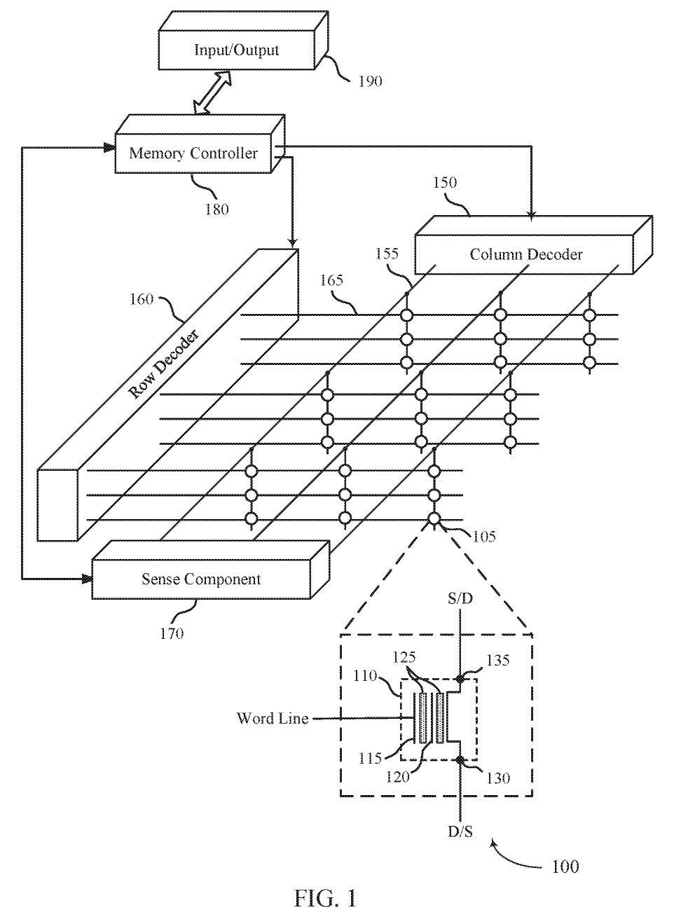

FIG. 1 shows an example of a memory device 100 that supports charge trapping NOR flash memory for stacked memory architectures in accordance with examples as disclosed herein. FIG. 1 is an illustrative representation of various components and features of the memory device 100. As such, the components and features of the memory device 100 are shown to illustrate functional interrelationships, and not necessarily physical positions within the memory device 100. Further, although some elements included in FIG. 1 are labeled with a numeric indicator, some other corresponding elements are not labeled, even though they are the same or would be understood to be similar, in an effort to increase visibility and clarity of the depicted features.

Developments in AI applications may lead to a memory solution that is capable of providing a high-density memory array combined with improved read performance (e.g., reduced latency and increased bandwidth) at a low cost, without increased write performances. AI applications may involve increased read operations having reduced latency metrics as compared to other applications, while also involving storing an increased quantity of data within a memory device. For example, AI applications may exhibit a different balance of read to write operations, as compared to other data storage applications, where write performance during AI inference operations may not be as vital to performance of the AI inference operations. For instance, in AI inference, a memory system may utilize static model data (e.g., model data is not updated during AI inference operations) and may perform a series of read operations to obtain the model data.

In some cases, memory systems may utilize stacks of volatile memory dies (e.g., HBM stacks, stacks of DRAM dies). In such cases, the memory system may utilize the volatile memory dies for both the training of an AI model and for performing AI inference operations. Such stacks of volatile memory dies may be associated with read performances that satisfy the various latency metrics for AI applications, however, such DRAM devices may be associated with an increased cost and have a relatively lower memory density (e.g., reduced storage capacity) as compared to other devices. For example, some memory systems may have space constraints (e.g., mobile units) and/or power constraints (e.g., battery powered), and building large volatile memories to handle AI applications may be challenging. Thus, memory solutions that maintain read performance, while also decreasing cost may be desired.

According to the techniques described herein, a memory system may implement one or more memory devices 100 into a stack of memory dies, which may enable the memory system to maintain read latencies and power consumption during AI inference operations, while also providing a decreased cost relative to stacks of volatile memory devices. For example, a stack of memory dies may include one or more memory devices 100. In some examples, the stack of memory dies may also include one or more volatile memory dies (e.g., dies including DRAM), while in other examples the stack of memory dies may primarily include the memory devices 100. The stack of memory dies may also include a logic die configured to access each of the memory dies of the stack using one or more vias, channels, or other components associated with the stack. In some examples, the logic die may access the memory dies of the stack in response to an access command received from a GPU or another component of the memory device 100.

A memory system may use the memory device 100 in AI inference operations. For example, the logic die may store AI model parameters in the memory devices 100. In response to one or more access commands, the logic die may read the AI model parameters from the memory devices 100 and transmit the parameters to the processing circuitry, which may use the AI model parameters to perform one or more AI inference operations.

The memory device 100 may include multiple charge trapping NOR Flash memory cells 105 in a pier and pillar architecture to increase the memory density (e.g., similar to 3D NAND three-bit-per-cell density) within the memory device 100 and improve read performance (e.g., have a relatively quicker random access speed, utilize decreased read voltages, have a higher bandwidth, among other advantages), while also reducing costs. For example, the memory device 100 may include multiple piers, where each pier may include multiple first memory cells 105 at a first end of the pier, and multiple second memory cells 105 at a second end of the pier.

To further increase the density (e.g., storage capacity) of the memory device 100, each memory cell 105 may be configured to store one or more bits of information. For example, each memory cell 105 may be configured as a single-level cell (SLC) to store a single bit of data or as a cell that stores two or more bits of data. For example, a memory cell 105 may be configured as a multi-level cell (MLC) that stores two bits of data, a triple-level cell (TLC) that stores three bits of data, a quad-level cell (QLC) that stores four bits of data, or a penta-level cell (PLC) that stores five bits of data. FIG. 1 illustrates a charge trapping NOR Flash memory cell 105 that includes a structure 110 that may be used to store two bits of data. The structure 110 may include a control gate 115 and a charge trapping structure 120, where the charge trapping structure 120 may, in some examples, be between two portions of dielectric material 125.

The structure 110 also may include a first node 130 (e.g., a source or drain) and a second node 135 (e.g., a drain or source). One or more logic values may be stored in the memory cell 105 by storing (e.g., writing) a quantity of electrons (e.g., an amount of charge) on the charge trapping structure 120. That is, the memory cell 105 may be programmed by trapping hot electrons into the charge trapping structure 120, where such electrons may be generated through channel-hot-electron mechanisms. Such charge trapping may occur at either side of the charge trapping structure 120 (e.g., at a first side to store a first bit of information and at a second side to store a second bit of information), thereby creating two bits of data store per memory cell 105.

As an illustrative example, each memory cell 105 may include a stack of materials including a first dielectric material 125 (e.g., gate oxide including silicon oxide, silicon nitride, or a silicon oxide multi-layer), a second dielectric material 125 (e.g., tunnel oxide including silicon oxide, silicon nitride, or a silicon oxide multi-layer), and a charge trapping structure 120 (e.g., silicon nitride) positioned between the dielectric materials 125.

Piers and pillars may be positioned in a two-dimensional array, where each pier may be positioned between a first pillar (e.g., source or drain) and a second pillar (e.g., drain or source) and be coupled with the first and second pillar via respective conductive paths, where such pillars may be utilized to access the memory cells at each pier. Each respective first memory cell 105 and each respective second memory cell 105 of a pier may be connected to a corresponding word line 165 (e.g., via the first dielectric material 125), where such word lines 165 may be utilized to access one of the multiple first memory cells or one of the multiple second memory cells. Each row of pillars may be connected to a respective source/drain (S/D) line (not shown) via a first transistor (thin film transistor) and each first transistor along each column of pillars may be connected to a corresponding bit line 155 (e.g., digit line or gate line). Accordingly, the S/D lines (e.g., access lines) may be perpendicular to the bit lines 155 (e.g., gate lines).

To access a memory cell 105, the column decoder 150 (e.g., gate line decoder) and a S/D decoder (not shown) may select the target memory cell 105 during programming (e.g., writing) or reading by biasing a single bit line 155 and two adjacent S/D lines, while the row decoder 160 may bias a word line 165 that corresponds to the memory cell 105. For example, the column decoder may activate a bit line 155, thereby selecting a column of pillars. Accordingly, the S/D decoder may select two adjacent S/D lines, thereby selecting a target pier, which may be positioned between the two selected pillars (e.g., the source and drain) on the selected column. Further, the row decoder 160 may bias the word line 165 that corresponds to the target memory cell 105.

As described herein, each pillar coupled with the target pier may be configured as a source or a drain according to which bit within the target memory cell 105 the memory device is to access. As such, to access a first bit of the target memory cell 105, the S/D decoder may configure the first pillar as a source by biasing the first pillar to a first voltage and may configure the second pillar as a drain by biasing the second pillar to a second voltage. Alternatively, to access the second bit of the target memory cell 105, the S/D decoder may configure the first pillar as a drain by biasing the first pillar to the second voltage and may configure the second pillar as a source by biasing the second pillar to the first voltage.

For example, to program a first bit of the target memory cell 105, the first pillar may be configured as the drain and biased to a first voltage (e.g., 5V), while the second pillar may be configured as the source and biased to a second voltage (e.g., 0V). The word line 165 associated with the target memory cell 105 may be biased to a third voltage (e.g., 9V). By doing so, a current may flow from the second pillar (e.g., the source) to the first pillar (e.g., the drain) through the charge trapping structure 120, thereby trapping hot electrons into the charge trapping structure 120 and programming the first bit.

Similarly, to program a second bit of the target memory cell 105, the second pillar may be configured as the drain and biased to a first voltage (e.g., 5V), while the first pillar may be configured as the source and biased to a second voltage (e.g., 0V). The word line 165 associated with the target memory cell 105 may be biased to a third voltage (e.g., 9V). By doing so, a current may flow from the first pillar (e.g., the source) to the second pillar (e.g., the drain), thereby trapping hot electrons into the charge trapping structure 120 and programming the second bit.

To read the first bit, the second pillar may be configured as the drain and biased to a first voltage (e.g., 1V), while the first pillar may be configured as the source and biased to a second voltage (e.g., 0V or ground). The word line 165 associated with the target memory cell 105 may be biased to a third voltage (e.g., 5V). By doing so, the sense component of the memory device 100 may sense the charge (e.g., first bit) stored in the charge trapping structure 120. Alternatively, to read the second bit, the first pillar may be configured as the drain and biased to a first voltage (e.g., 1V), while the second pillar may be configured as the source and biased to a second voltage (e.g., 0V or ground). The word line 165 associated with the memory cell 105 may be biased to a third voltage (e.g., 5V). By doing so, the sense component of the memory device 100 may sense the charge (e.g., second bit) stored in the charge trapping structure 120.

The memory cells 105 of the memory device 100 may be erased in blocks (e.g., sectors or groups) that include adjacent memory cells 105 associated with a same word line deck (e.g., same word line 165) across one or more piers. That is, to protect against over- or under-erasure, all bits in a block are pre-programmed and then all S/D contacts (e.g., pillars) in the block are positively biased for erasing all the bits in the block. Accordingly, each memory cell 105 within the block may be erased via a through hole injection generated by the junction between the conductive paths (e.g., n-type polysilicon) and the conductive layer (e.g., p-type polysilicon). For example, the memory controller 180 may verify that all bits stored in the memory cell 105 are in an erased state (e.g., store a logic value of ‘0’), the memory controller 180 may reprogram each of the respective two bits of the memory cells 105 to a uniform state (e.g., each bit is set to ‘1’). Based on reprogramming the bits to a logical ‘1’, the first and second pillars may be biased to a first voltage (e.g., 5V) and the word line 165 may be biased to a third voltage (e.g., -6V). By doing so, the bits of the memory cell may be erased.

A memory controller 180 may control the operation (e.g., read, write, re-write, refresh) of memory cells 105 through the various components (e.g., row decoder 160, column decoder 150, sense component 170, S/D decoder) and interface with an input/output function 190 (e.g., such as a host system). In some cases, one or more of a row decoder 160, a column decoder 150, a sense component 170, and a S/D decoder may be co-located with a memory controller 180. A memory controller 180 may generate row and column address signals in order to activate a desired word line 165, bit line 155, and adjacent S/D lines. In some examples, a memory controller 180 may generate and control various voltages or currents used during the operation of memory device 100.

In some examples, the memory device 100 may be referred to as a parallel memory device. For example, the memory device 100 may include multiple arrays of memory cells 105, where each of the memory cells 105 of an array have a parallel connection with decoding lines (e.g., word lines 165, S/D lines, bit lines 155, gate lines, among other examples). In contrast, a NAND memory device may be referred to as a serial memory device. For example, a NAND memory device may include multiple arrays of memory cells, where each of the memory cells of an array have a serial connection with decoding lines.

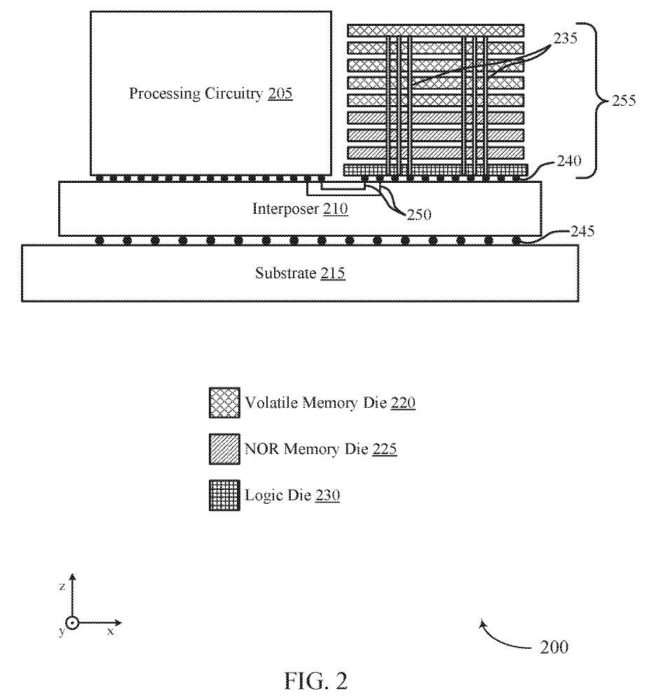

FIG. 2 shows an example of a system 200 (e.g., a semiconductor system, a system of coupled semiconductor dies, an HBM system, a 3D stacked memory system) that supports charge trapping NOR flash memory for stacked memory architectures in accordance with examples as disclosed herein. Aspects of the system 200 may implement aspects of the memory device 100. For example, the system 200 may include one or more NOR memory dies 225, where each NOR memory die 225 may be an example of the memory device 100, as described herein with reference to FIG. 1. The techniques described in the context of the system 200 enable the use of the one or more NOR memory dies 225 within a stack of memory dies 255.

The system 200 may include processing circuitry 205 coupled with an interposer 210, a substrate 215, and a stack 255 (e.g., a stack of memory dies). For example, the system 200 may include processing circuitry 205, such as a GPU, central processing unit (CPU), or one or more controllers, among other examples, which may be configured to transmit one or more commands (e.g., associated with access operations, AI model operations) to the stack 255.

The processing circuitry 205 may be coupled with the interposer 210. In some examples, the processing circuitry 205 and the interposer 210 may be physically and electrically coupled by multiple connectors 240, which may be examples of conductive micro-bumps. The interposer 210 may include one or more channels 250, which may couple the processing circuitry 205 and the stack 255. For example, the processing circuitry 205 may transmit one or more access commands to the stack 255 via the channels 250 of the interposer 210. In some examples, the interposer 210 may be coupled (e.g., physically, electrically) to the substrate 215 via multiple connectors 245, such that the processing circuitry 205 and the stack 255 may be located over the interposer 210 in a z-direction, and the interposer 210 may be located over the substrate 215 in the z-direction.

The system 200 may be utilized for AI applications. Such AI applications may involve increased read operations associated with (e.g., accesses of) the memory dies of the stack 255, where such accesses may be associated with various latency metrics. Additionally, such AI applications may involve storing a relatively large quantity of data within the memory dies of the stack 255. In some cases, read latencies associated with some types of memory dies may not satisfy the latency metrics associated with the AI applications. For example, some AI applications may include large numbers of read operations during a short duration. Alternatively, some types of memory dies may not have sufficient memory density (e.g., sufficient storage capacity) to store the increased quantity of data for AI applications, may not be cost effective, or both. For example, the stack 255 may include volatile memory dies 220 that may be associated with read performances that may satisfy the various latency metrics for AI applications, however, a stack 255 including the volatile memory dies 220 may be associated with an increased cost and have a relatively lower memory density (e.g., reduced storage capacity) when compared to a stack of another type of memory die.

To increase memory density and access operation performances of the stack 255, while maintaining a relatively low cost system, non-volatile, 3D, charge trapping NOR flash memory dies (e.g., the NOR memory dies 225) may be implemented in the stack 255. For example, the stack 255 may include one or more charge trapping NOR memory dies 225. Each NOR memory die 225 may include multiple memory arrays. Each memory array may include multiple memory cells that may each include a charge trapping layer and that may be coupled in parallel across each respective NOR memory die 225. For example, each memory cell of a NOR memory die 225 may include a stack of materials including a first dielectric material (e.g., gate oxide including silicon oxide, silicon nitride, or a silicon oxide multi-layer), a second dielectric material (e.g., tunnel oxide including silicon oxide, silicon nitride, or a silicon oxide multi-layer), and a charge trapping layer (e.g., silicon nitride) positioned between the two dielectric materials.

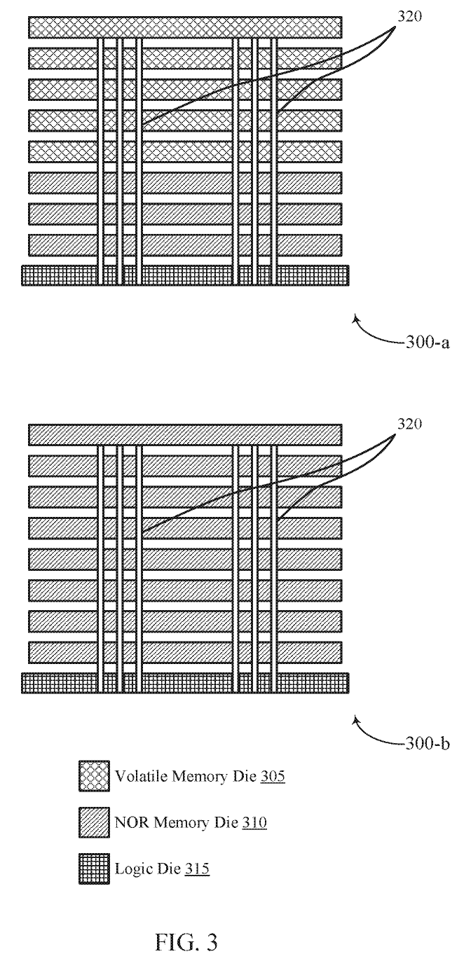

The stack 255 may also include one or more other memory dies and vias 235. In a first example, and as further described herein with reference to FIG. 3, the stack 255 may include one or more of the volatile memory dies 220. The volatile memory dies 220 may be examples of DRAM memory dies that each include multiple DRAM memory cells. In a second example, and as further described herein with reference to FIG. 3, the stack 255 may primarily include the NOR memory dies 225 (e.g., not illustrated in FIG. 2).

Each of the volatile memory dies 220 may be associated with training one or more AI models, which may be performed at the processing circuitry 205, and each of the NOR memory dies 225 may be associated with storage of AI model parameters associated with performance of AI inference operations. In the case that the stack 255 includes both the NOR memory dies 225 and the volatile memory dies 220, the stack 255 may be used for both training of AI models (e.g., via the volatile memory dies 220) and used for AI inference operations (e.g., via the NOR memory dies). In the case that the stack 255 includes primarily the NOR memory dies 225, the stack 255 may be used for AI inference operations. While illustrated as including eight (8) memory dies, the stack 255 may include any quantity of memory dies, and any combination of volatile memory dies 220 and NOR memory dies 225.

The stack 255 may also include a logic die 230. The logic die 230 may be coupled with each of the memory dies of the stack 255 (e.g., the volatile memory dies 220, the NOR memory dies 225) via the vias 235. Each of the vias 235 may extend along the z-direction and through each of the memory dies of the stack 255 and may electrically couple a portion of each of the memory dies (e.g., the volatile memory dies 220, the NOR memory dies 225) with the logic die 230. For example, the logic die 230 may be configured to transfer information between each NOR memory die 225 and each volatile memory die 220 via the vias 235.

The logic die 230 may be configured to access each of the memory dies of the stack 255 (e.g., the volatile memory dies 220, the NOR memory dies 225) using the vias 235, the channels 250, or other components associated with the stack 255. For example, the logic die 230 of the stack 255 may be coupled with the processing circuitry 205 via the channels 250 of the interposer 210, and may be configured to access the memory dies via the vias 235 in response to receiving a command from the processing circuitry 205.

As described herein, the processing circuitry 205 may utilize the volatile memory dies 220 to generate one or more model parameters associated with an AI model and may utilize the NOR memory dies 225 to store the generated model parameters. For example, the processing circuitry 205 may train the AI model to generate the one or more model parameters, where the logic die 230 may store, at least temporarily or during the training operation, the one or more model parameters in the volatile memory dies 220 via the channels 250 (e.g., and the vias 235). In response to generating the one or more model parameters, the processing circuitry 205 (e.g., via the logic die 230) may read the one or more model parameters from the volatile memory dies 220 and store the one or more model parameters in the NOR memory dies 225 via the vias 235.

According to generating the one or more model parameters, the processing circuitry 205 may utilize the NOR memory dies 225 to perform the AI inference operation. AI inference may be the process of using a trained machine learning model to make a prediction or decision (e.g., be the phase where the trained model is put into action). For example, the processing circuitry 205 may transmit, via the channels 250, one or more read commands to access the one or more model parameters at the NOR memory dies 220. Based on (e.g., in response to) receiving the one or more read commands, the logic die 230 may obtain, via the vias 235, the one or more model parameters from the NOR memory dies 225 (e.g., either via a sequential read or random read based on the address of the one or more model parameters) and output the one or more model parameters to the processing circuitry 205 via the channels 250.

The processing circuitry 205 may perform a series of computations to produce a result, where such computations may involve matrix multiplications, convolutions, or other mathematical operations, depending on the type of model. In response to performing the series of computations, the processing circuitry 205 may transform the result into an output, for example, by converting numeric scores into category labels, or applying a threshold to a probability. Based on obtaining the output, the processing circuitry 205 may transmit the output of the AI model to the end user or application, which may involve sending a response to a web request, or updating a database, among other examples.

In some examples, the processing circuitry 205 may update the one or more model parameters stored in the NOR memory dies 225. To do so, the processing circuitry 205 may transmit one or more read commands to the logic die 230 via the channels 250, where the logic die 230 may obtain (e.g., read, receive) the one or more model parameters from the NOR memory dies 225 via the vias 235. In response, the logic die 230 may output the one or more model parameters to the processing circuitry 205 via the channels 250. Accordingly, the processing circuitry 205 may perform a series of training computations on a data set and using the one or more model parameters to generate one or more updated model parameters.

In some examples, the processing circuitry 205 may store the one or more updated model parameters, at least temporarily, in the volatile memory dies 220 during the update operation. For example, the processing circuitry 205 may obtain a first updated model parameter, transmit the first updated model parameter to the logic die 230 via the channels 250, where the logic die 230 may store the first updated model parameter in the volatile memory dies 220. In response to generating the one or more updated model parameters, the processing circuitry 205 may write the one or more updated model parameters to the NOR memory dies 225 via the logic die 230.

In some examples, the system 200 may include multiple stacks 255. For example, the system 200 may include a first stack 255 including the NOR memory dies 225 and a second stack 255 including the volatile memory dies 220. In such examples, the system 200 may utilize the second stack 255 for training (e.g., and updating) of AI models that may be operated by the processing circuitry 205, and utilize the first stack 255 in storage of the model parameters and for performance of AI inference operations. As described herein the system 200 may include any quantity of stacks 255, where each stack 255 may include any combination of the volatile memory dies 220 and the NOR memory dies 225.

FIG. 3 shows an example of memory die architectures 300 that support charge trapping NOR flash memory for stacked memory architectures in accordance with examples as disclosed herein. Aspects of the memory die architectures 300 may implement, or be implemented by, aspects of the memory device 100 or the system 200. For example, the memory die architecture 300-a and the memory die architecture 300-b may include one or more volatile memory dies 305, one or more NOR memory dies 310, one or more logic dies 315, and vias 320, which may be examples volatile memory dies 220, NOR memory dies 225, logic dies 230, and vias 235, or combinations thereof, as described herein with reference to FIG. 2. Each of the memory die architectures 300 may be examples of a stack 255 as described with reference to FIG. 2. Further, the memory die architectures 300 may be implemented within a memory system, such as the system 200, as described herein with reference to FIG. 2, where the memory system may utilize such memory die architectures to perform AI inference operations, AI training operations, or both.

As described herein, a stack (e.g., a stack of memory dies) may include one or more memory die architectures 300 that include varying combinations of the volatile memory dies 305 and the NOR memory dies 310. For example, the stack may implement the memory die architecture 300-a, such that the stack may include a logic die 315 coupled with a combination of the volatile memory dies 305 and the NOR memory dies 310 via one or more vias 320. While the memory die architecture 300-a illustrates three (3) NOR memory dies 310 and five (5) volatile memory dies 305, the stack may include any combination of the volatile memory dies 305 and the NOR memory dies 310.

Accordingly, a stack that implements the memory die architecture 300-a may be used for AI model training operations, storage of model parameters associated with AI inference operations, or both. For example, processing circuitry (e.g., processing circuitry 205) of the memory system may train an AI model to obtain one or more AI model parameters using data. For example, the memory system, via the processing circuitry, may train the AI model on a data set to generate the one or more AI model parameters.

Accordingly, the processing circuitry may transmit the generated model parameters to the logic die 315 of the memory die architecture 300-a, where the logic die 315 may write the model parameters (e.g., temporarily, during the AI model training operations, until an idle mode of the memory device) to one or more of the volatile memory dies 305 using the vias 320. In response to completion of the training operation, the memory system, via the processing circuitry, may transfer the model parameters from the volatile memory dies 305 to the NOR memory dies 310 to use in future AI inference operations. For example, the logic die 315 may obtain the model parameters from the volatile memory dies 305 and may write the model parameters to one or more of the NOR memory dies 310 via the vias 320.

The memory system, via the processing circuitry, may perform an AI inference operation using the AI model parameters stored in the NOR memory dies 310. For example, the logic die 315 may receive one or more access commands (e.g., read commands) from the processing circuitry, where the access commands may indicate an address of the one or more of the AI model parameters. In response, the logic die 315 may obtain the model parameters from the NOR memory dies 310 (e.g., using the vias 320) in accordance with the access commands. In response to obtaining the model parameters, the logic die 315 may transmit the model parameters to the processing circuitry of the memory system. Based on receiving the model parameters obtained from the NOR memory dies 310, the processing circuitry may execute an AI inference operation using the model parameters, as described herein with reference to FIG. 2.

In some other examples, a stack (e.g., stack of memory dies) may implement memory die architectures 300 that do not include varying combinations of the volatile memory dies 305 and the NOR memory dies 310, but rather include primarily (e.g., only) the NOR memory dies 310. For example, the stack may implement the memory die architecture 300-b, such that the stack includes a logic die 315 coupled with the NOR memory dies 310 via the one or more vias 320. While the memory die architecture 300-b illustrates eight (8) NOR memory dies 310, a stack may include any quantity of the NOR memory dies 310.

Accordingly, a stack that implements the memory die architecture 300-b may be used for storage of model parameters associated with AI inference operations. For example, processing circuitry of the memory system may train an AI model to obtain one or more AI model parameters using data, for example, using a second stack of memory dies that include the volatile memory dies 305, the NOR memory dies 310, or both. The logic die 315 may receive the generated model parameters, such that the logic die 315 may store the model parameters to one or more of the NOR memory dies 310 using the vias 320 for use in future AI inference operations.

The memory system, via the processing circuitry, may perform an AI inference operation using the AI model parameters stored to the NOR memory dies 310. As described herein, the logic die 315 of the memory die architecture 300-b may receive one or more access commands associated with the model parameters, and may obtain the model parameters from the NOR memory dies 310 (e.g., using the vias 320) in accordance with the commands. In response to obtaining the model parameters, the logic die 315 may transmit the model parameters to the processing circuitry, where the processing circuitry may execute an AI inference operation using the model parameters, as described herein with reference to FIG. 2.

Implementation of the NOR memory dies 310 in the memory die architectures 300 may increase memory density of and access operation performance at the memory die architectures 300. For example, use of NOR memory dies 310 in a memory die architecture 300 may be associated with increased read performance and low latency, which may similarly increase performance of large AI models. Additionally, or alternatively, use of NOR memory dies 310 in a memory die architecture 300 may increase memory capacity of the memory die architecture 300 without decreasing bandwidth of the memory die architecture 300, as NOR memory dies 310 may be associated with a higher quantity of terabyte (TB) capacity relative to the volatile memory dies 305. NOR memory dies 310 may also decrease costs of the associated memory device, as the cost of NOR memory dies 310 may be less than a cost of the volatile memory dies 305. Use of NOR memory dies 310 in a memory die architecture 300 may also decrease power used by the memory device, as less refresh operations may be implemented with use of the NOR memory dies 310 relative to refresh operations for use of the volatile memory dies 305 (e.g., due to the non-volatility of the NOR memory dies 310).

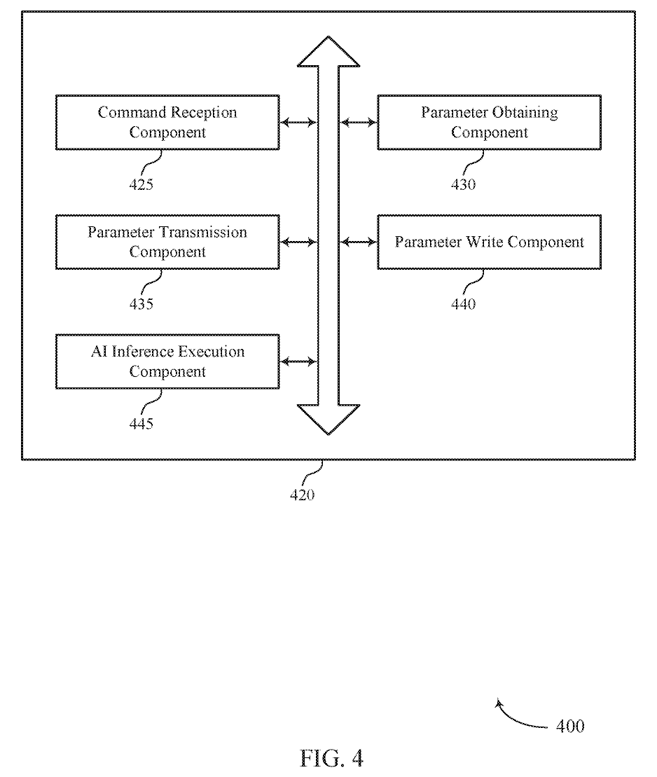

FIG. 4 shows a block diagram 400 of a memory system 420 that supports charge trapping NOR flash memory for stacked memory architectures in accordance with examples as disclosed herein. The memory system 420 may be an example of aspects of a memory system as described with reference to FIGS. 1 through 3. The memory system 420, or various components thereof, may be an example of means for performing various aspects of charge trapping NOR flash memory for stacked memory architectures as described herein. For example, the memory system 420 may include a command reception component 425, a parameter obtaining component 430, a parameter transmission component 435, a parameter write component 440, an AI inference execution component 445, or any combination thereof. Each of these components, or components of subcomponents thereof (e.g., one or more processors, one or more memories), may communicate, directly or indirectly, with one another (e.g., via one or more buses).

The memory system 420 may support operating a memory system in accordance with examples as disclosed herein. The command reception component 425 may be configured as or otherwise support a means for receiving, at a logic die of a stack of memory dies, a plurality of access commands directed to one or more model parameters associated with an AI model, where the AI model is operated by processing circuitry coupled with the stack of memory dies, and where the stack of memory dies includes a plurality of NOR memory dies and a plurality of volatile memory dies. The parameter obtaining component 430 may be configured as or otherwise support a means for obtaining, at the logic die, the one or more model parameters from the plurality of NOR memory dies in accordance with receiving the plurality of access commands. The parameter transmission component 435 may be configured as or otherwise support a means for transmitting, from the logic die, the one or more model parameters to the processing circuitry in response to obtaining the one or more model parameters from the plurality of NOR memory dies.

In some examples, the parameter write component 440 may be configured as or otherwise support a means for writing, by the logic die, the one or more model parameters to the plurality of volatile memory dies as part of a training operation for the AI model at the processing circuitry, where the one or more model parameters are generated in accordance with the training operation.

In some examples, the AI inference execution component 445 may be configured as or otherwise support a means for executing, by the processing circuitry, an AI inference operation using the one or more model parameters in accordance with transmitting the one or more model parameters from the logic die to the processing circuitry.

In some examples, the parameter obtaining component 430 may be configured as or otherwise support a means for obtaining, at the logic die and from the processing circuitry, the one or more model parameters. In some examples, the parameter write component 440 may be configured as or otherwise support a means for writing, by the logic die to the plurality of NOR memory dies, the one or more model parameters, where executing the AI inference operation is in accordance with writing the one or more model parameters to the plurality of NOR memory dies.

In some examples, the stack of memory dies further includes a plurality of vias, each via of the plurality of vias coupling a respective portion of each NOR memory die of the plurality of NOR memory dies and a respective portion of each volatile memory die of the plurality of volatile memory dies with the logic die. In some examples, obtaining the one or more model parameters is in accordance with the plurality of vias.

In some examples, the plurality of NOR memory dies include NOR memory cells. In some examples, the plurality of volatile memory dies include volatile memory cells.

In some examples, each NOR memory cell of the plurality of NOR memory dies includes a first dielectric material, a second dielectric material, and a charge trapping layer between the first dielectric material and the second dielectric material.

In some examples, each NOR memory cell of the plurality of NOR memory dies stores a first bit at a first end of the charge trapping layer in accordance with trapping a first plurality of electrons at the first end of the charge trapping layer, and stores a second bit at a second end of the charge trapping layer in accordance with trapping a second plurality of electrons at the second end of the charge trapping layer.

In some examples, the described functionality of the memory system 420, or various components thereof, may be supported by or may refer to at least a portion of at least one processor, where such at least one processor may include one or more processing elements (e.g., a controller, a microprocessor, a microcontroller, a digital signal processor, a state machine, discrete gate logic, discrete transistor logic, discrete hardware components, or any combination of one or more of such elements). In some examples, the described functionality of the memory system 420, or various components thereof, may be implemented at least in part by instructions (e.g., stored in memory, non-transitory computer-readable medium) executable by such at least one processor.

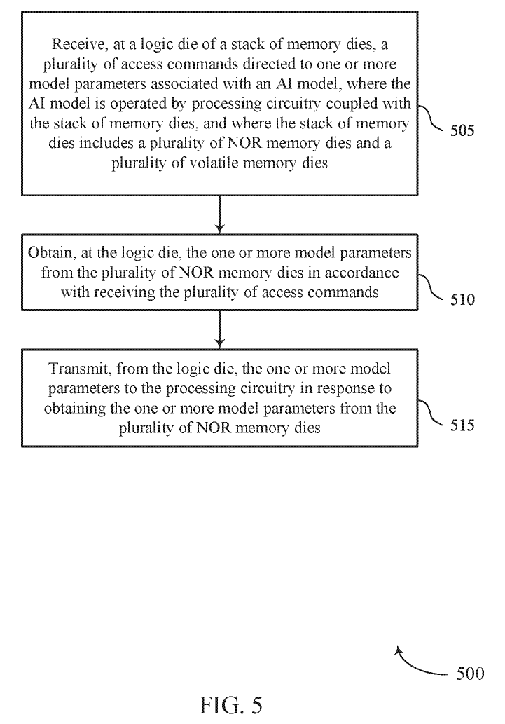

FIG. 5 shows a flowchart illustrating a method 500 that supports charge trapping NOR flash memory for stacked memory architectures in accordance with examples as disclosed herein. The operations of method 500 may be implemented by a memory system or its components as described herein. For example, the operations of method 500 may be performed by a memory system as described with reference to FIGS. 1 through 4. In some examples, a memory system may execute a set of instructions to control the functional elements of the device to perform the described functions. Additionally, or alternatively, the memory system may perform aspects of the described functions using special-purpose hardware.

At 505, the method may include receiving, at a logic die of a stack of memory dies, a plurality of access commands directed to one or more model parameters associated with an AI model, where the AI model is operated by processing circuitry coupled with the stack of memory dies, and where the stack of memory dies includes a plurality of NOR memory dies and a plurality of volatile memory dies. In some examples, aspects of the operations of 505 may be performed by a command reception component 425 as described with reference to FIG. 4.

At 510, the method may include obtaining, at the logic die, the one or more model parameters from the plurality of NOR memory dies in accordance with receiving the plurality of access commands. In some examples, aspects of the operations of 510 may be performed by a parameter obtaining component 430 as described with reference to FIG. 4.

At 515, the method may include transmitting, from the logic die, the one or more model parameters to the processing circuitry in response to obtaining the one or more model parameters from the plurality of NOR memory dies. In some examples, aspects of the operations of 515 may be performed by a parameter transmission component 435 as described with reference to FIG. 4.

In some examples, an apparatus as described herein may perform a method or methods, such as the method 500. The apparatus may include features, circuitry, logic, means, or instructions (e.g., a non-transitory computer-readable medium storing instructions executable by a processor), or any combination thereof for performing the following aspects of the present disclosure:

Aspect 1: A method, apparatus, or non-transitory computer-readable medium including operations, features, circuitry, logic, means, or instructions, or any combination thereof for receiving, at a logic die of a stack of memory dies, a plurality of access commands directed to one or more model parameters associated with an artificial intelligence (AI) model, where the AI model is operated by processing circuitry coupled with the stack of memory dies, and where the stack of memory dies includes a plurality of NOR memory dies and a plurality of volatile memory dies; obtaining, at the logic die, the one or more model parameters from the plurality of NOR memory dies in accordance with receiving the plurality of access commands; and transmitting, from the logic die, the one or more model parameters to the processing circuitry in response to obtaining the one or more model parameters from the plurality of NOR memory dies.

Aspect 2: The method, apparatus, or non-transitory computer-readable medium of aspect 1, further including operations, features, circuitry, logic, means, or instructions, or any combination thereof for writing, by the logic die, the one or more model parameters to the plurality of volatile memory dies as part of a training operation for the AI model at the processing circuitry, where the one or more model parameters are generated in accordance with the training operation.

Aspect 3: The method, apparatus, or non-transitory computer-readable medium of any of aspects 1 through 2, further including operations, features, circuitry, logic, means, or instructions, or any combination thereof for executing, by the processing circuitry, an AI inference operation using the one or more model parameters in accordance with transmitting the one or more model parameters from the logic die to the processing circuitry.

Aspect 4: The method, apparatus, or non-transitory computer-readable medium of aspect 3, further including operations, features, circuitry, logic, means, or instructions, or any combination thereof for obtaining, at the logic die and from the processing circuitry, the one or more model parameters and writing, by the logic die to the plurality of NOR memory dies, the one or more model parameters, where executing the AI inference operation is in accordance with writing the one or more model parameters to the plurality of NOR memory dies.

Aspect 5: The method, apparatus, or non-transitory computer-readable medium of any of aspects 1 through 4, where the stack of memory dies further includes a plurality of vias, each via of the plurality of vias coupling a respective portion of each NOR memory die of the plurality of NOR memory dies and a respective portion of each volatile memory die of the plurality of volatile memory dies with the logic die and obtaining the one or more model parameters is in accordance with the plurality of vias.

Aspect 6: The method, apparatus, or non-transitory computer-readable medium of any of aspects 1through 5, where the plurality of NOR memory dies include NOR memory cells and the plurality of volatile memory dies include volatile memory cells.

Aspect 7: The method, apparatus, or non-transitory computer-readable medium of aspect 6, where each NOR memory cell of the plurality of NOR memory dies includes a first dielectric material, a second dielectric material, and a charge trapping layer between the first dielectric material and the second dielectric material.

Aspect 8: The method, apparatus, or non-transitory computer-readable medium of aspect 7, where each NOR memory cell of the plurality of NOR memory dies stores a first bit at a first end of the charge trapping layer in accordance with trapping a first plurality of electrons at the first end of the charge trapping layer, and stores a second bit at a second end of the charge trapping layer in accordance with trapping a second plurality of electrons at the second end of the charge trapping layer.

It should be noted that the aspects described herein describe possible implementations, and that the operations and the steps may be rearranged or otherwise modified and that other implementations are possible. Further, portions from two or more of the methods may be combined.

An apparatus is described. The following provides an overview of aspects of the apparatus as described herein:

Aspect 9: A memory system, including: a first memory device including a stack of memory dies, where the stack of memory dies includes: a plurality of volatile memory dies including volatile memory cells; a plurality of non-volatile NOR memory dies including NOR memory cells; and a logic die coupled with the plurality of volatile memory dies and the plurality of NOR memory dies, the logic die configured to transfer information between both the plurality of volatile memory dies and the plurality of NOR memory dies in response to one or more access commands.

Aspect 10: The memory system of aspect 9, where the stack of memory dies further includes: a plurality of vias, each via of the plurality of vias coupling a respective portion of each NOR memory die of the plurality of NOR memory dies and a respective portion of each volatile memory die of the plurality of volatile memory dies with the logic die, where the logic die is configured to transfer the information between each NOR memory die of the plurality of NOR memory dies and each volatile memory die of the plurality of volatile memory dies via the plurality of vias.

Aspect 11: The memory system of any of aspects 9 through 10, further including: an interposer coupled with the first memory device and including one or more channels; and processing circuitry coupled with the interposer and configured to transmit the one or more access commands to the first memory device via the one or more channels of the interposer.

Aspect 12: The memory system of any of aspects 9 through 11, where, to transfer the information, the logic die is configured to: read the information from each NOR memory die of the plurality of NOR memory dies; and read the information from or write the information to each volatile memory die of the plurality of volatile memory dies.

Aspect 13: The memory system of aspect 12, where: each volatile memory die of the plurality of volatile memory dies is associated with training one or more AI models; and each NOR memory die of the plurality of NOR memory dies is associated with performing inference operations using the one or more AI models.

Aspect14: The memory system of any of aspects 9 through 13, where the memory system further includes: a second memory device including a second stack of memory dies, where the second stack of memory dies includes: a plurality of second NOR memory dies; and a second logic die coupled with the plurality of second NOR memory dies and configured to read second information from the plurality of NOR memory dies in response to one or more second access commands.

Aspect 15: The memory system of aspect 14, where each NOR memory die of the plurality of NOR memory dies is associated with performing inference operations using one or more AI models.

Aspect 16: The memory system of any of aspects 9through 15, where each NOR memory cell of the NOR memory cells includes a first dielectric material, a second dielectric material, and a charge trapping layer between the first dielectric material and the second dielectric material.

Aspect 17: The memory system of aspect 16, where each NOR memory cell of the NOR memory cells stores a first bit at a first end of the charge trapping layer in accordance with trapping a first plurality of electrons at the first end of the charge trapping layer, and stores a second bit at a second end of the charge trapping layer in accordance with trapping a second plurality of electrons at the second end of the charge trapping layer.

Aspect 18: The memory system of any of aspects 9 through 17, where the NOR memory cells are non-volatile memory cells.

Aspect 19: The memory system of any of aspects 9 through 18, where: each NOR memory die of the plurality of NOR memory dies includes a respective plurality of arrays, each array of the respective plurality of arrays includes a respective plurality of NOR memory cells, and the respective plurality of NOR memory cells of a corresponding array are coupled in parallel.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (e.g., in conductive contact with, connected with, coupled with) one another if there is any electrical path (e.g., conductive path) between the components that can, at any time, support the flow of signals (e.g., charge, current, voltage) between the components. A conductive path between components that are in electronic communication with each other (e.g., in conductive contact with, connected with, coupled with) may be an open circuit or a closed circuit based on the operation of the device that includes the connected components. A conductive path between connected components may be a direct conductive path between the components or may be an indirect conductive path that includes intermediate components, such as switches, transistors, or other components. In some examples, the flow of signals between the connected components may be interrupted for a time, for example, using one or more intermediate components such as switches or transistors.

The term “coupling” (e.g., “electrically coupling”) may refer to condition of moving from an open-circuit relationship between components in which signals are not presently capable of being communicated between the components (e.g., over a conductive path) to a closed-circuit relationship between components in which signals are capable of being communicated between components (e.g., over the conductive path). When a component, such as a controller, couples other components together, the component may initiate a change that allows signals to flow between the other components over a conductive path that previously did not permit signals to flow.

A switching component (e.g., a transistor) discussed herein may be a field-effect transistor (FET), and may include a source (e.g., a source terminal), a drain (e.g., a drain terminal), a channel between the source and drain, and a gate (e.g., a gate terminal). A conductivity of the channel may be controlled (e.g., modulated) by applying a voltage to the gate which, in some examples, may result in the channel becoming conductive. A switching component may be an example of an n-type FET or a p-type FET.

The description set forth herein, in connection with the appended drawings, describes example configurations and does not represent all the examples that may be implemented or that are within the scope of the claims. The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Similar components may be distinguished by following the reference label by one or more dashes and additional labeling that distinguishes among the similar components. If just the first reference label is used in the specification, the description is applicable to any one of the similar components having the same first reference label irrespective of the additional reference labels.

The functions described herein may be implemented in hardware, software executed by a processing system (e.g., one or more processors, one or more controllers, control circuitry processing circuitry, logic circuitry), firmware, or any combination thereof. If implemented in software executed by a processing system, the functions may be stored on or transmitted over as one or more instructions (e.g., code) on a computer-readable medium. Due to the nature of software, functions described herein can be implemented using software executed by a processing system, hardware, firmware, hardwiring, or combinations of any of these. Features implementing functions may be physically located at various positions, including being distributed such that portions of functions are implemented at different physical locations.

Illustrative blocks and modules described herein may be implemented or performed with one or more processors, such as a DSP, an ASIC, an FPGA, discrete gate logic, discrete transistor logic, discrete hardware components, other programmable logic device, or any combination thereof designed to perform the functions described herein. A processor may be an example of a microprocessor, a controller, a microcontroller, a state machine, or other types of processors. A processor may also be implemented as at least one of one or more computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

Computer-readable media includes both non-transitory computer storage media and communication media including any medium that facilitates transfer of a computer program from one place to another. A non-transitory storage medium may be any available medium, or combination of multiple media, which can be accessed by a computer. By way of example, and not limitation, non-transitory computer-readable media can comprise RAM, ROM, electrically erasable programmable read-only memory (EEPROM), optical disk storage, magnetic disk storage or other magnetic storage devices, or any other non-transitory medium or combination of media that can be used to carry or store desired program code means in the form of instructions or data structures and that can be accessed by a computer, or one or more processors.

The descriptions and drawings are provided to enable a person having ordinary skill in the art to make or use the disclosure. Various modifications to the disclosure will be apparent to the person having ordinary skill in the art, and the techniques disclosed herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A memory system, comprising:
a first memory device comprising a stack of memory dies, wherein the stack of memory dies comprises:
a plurality of volatile memory dies comprising volatile memory cells;
a plurality of non-volatile not-OR (NOR) memory dies comprising NOR memory cells; and
a logic die coupled with the plurality of volatile memory dies and the plurality of NOR memory dies, the logic die configured to transfer information between both the plurality of volatile memory dies and the plurality of NOR memory dies in response to one or more access commands.

2. The memory system of claim 1, wherein the stack of memory dies further comprises:
a plurality of vias, each via of the plurality of vias coupling a respective portion of each NOR memory die of the plurality of NOR memory dies and a respective portion of each volatile memory die of the plurality of volatile memory dies with the logic die, wherein the logic die is configured to transfer the information between each NOR memory die of the plurality of NOR memory dies and each volatile memory die of the plurality of volatile memory dies via the plurality of vias.

3. The memory system of claim 1, further comprising:
an interposer coupled with the first memory device and comprising one or more channels; and
processing circuitry coupled with the interposer and configured to transmit the one or more access commands to the first memory device via the one or more channels of the interposer.

4. The memory system of claim 1, wherein, to transfer the information, the logic die is configured to:
read the information from each NOR memory die of the plurality of NOR memory dies; and
read the information from or write the information to each volatile memory die of the plurality of volatile memory dies.

5. The memory system of claim 4, wherein:
each volatile memory die of the plurality of volatile memory dies is associated with training one or more artificial intelligence (AI) models; and
each NOR memory die of the plurality of NOR memory dies is associated with performing inference operations using the one or more AI models.

6. The memory system of claim 1, wherein the memory system further comprises:
a second memory device comprising a second stack of memory dies, wherein the second stack of memory dies comprises:
a plurality of second NOR memory dies; and
a second logic die coupled with the plurality of second NOR memory dies and configured to read second information from the plurality of NOR memory dies in response to one or more second access commands.

7. The memory system of claim 6, wherein each NOR memory die of the plurality of NOR memory dies is associated with performing inference operations using one or more artificial intelligence (AI) models.

8. The memory system of claim 1, wherein each NOR memory cell of the NOR memory cells comprises a first dielectric material, a second dielectric material, and a charge trapping layer between the first dielectric material and the second dielectric material.

9. The memory system of claim 8, wherein each NOR memory cell of the NOR memory cells stores a first bit at a first end of the charge trapping layer in accordance with trapping a first plurality of electrons at the first end of the charge trapping layer, and stores a second bit at a second end of the charge trapping layer in accordance with trapping a second plurality of electrons at the second end of the charge trapping layer.

10. The memory system of claim 1, wherein the NOR memory cells are non-volatile memory cells.

11. The memory system of claim 1, wherein:
each NOR memory die of the plurality of NOR memory dies comprises a respective plurality of arrays,
each array of the respective plurality of arrays comprises a respective plurality of NOR memory cells, and
the respective plurality of NOR memory cells of a corresponding array are coupled in parallel.

12. A memory system, comprising:
a stack of memory dies comprising a logic die coupled with a plurality of NOR memory dies and a plurality of volatile memory dies; and
processing circuitry coupled with the stack of memory dies and configured to cause the memory system to:
receive, at the logic die, a plurality of access commands directed to one or more model parameters associated with an artificial intelligence (AI) model, wherein the AI model is operated by the processing circuitry;
obtain, at the logic die, the one or more model parameters from the plurality of NOR memory dies in accordance with receiving the plurality of access commands; and
transmit, from the logic die, the one or more model parameters to the processing circuitry in response to obtaining the one or more model parameters from the plurality of NOR memory dies.

13. The memory system of claim 12, wherein the processing circuitry is further configured to cause the memory system to:
write, by the logic die, the one or more model parameters to the plurality of volatile memory dies as part of a training operation for the AI model at the processing circuitry, wherein the one or more model parameters are generated in accordance with the training operation.

14. The memory system of claim 12, wherein the processing circuitry is further configured to cause the memory system to:
execute, by the processing circuitry, an AI inference operation using the one or more model parameters in accordance with transmitting the one or more model parameters from the logic die to the processing circuitry.

15. The memory system of claim 14, wherein the processing circuitry is further configured to cause the memory system to:
obtain, at the logic die and from the processing circuitry, the one or more model parameters; and
write, by the logic die to the plurality of NOR memory dies, the one or more model parameters, wherein executing the AI inference operation is in accordance with writing the one or more model parameters to the plurality of NOR memory dies.

16. The memory system of claim 12, wherein:
the stack of memory dies further comprises a plurality of vias, each via of the plurality of vias coupling a respective portion of each NOR memory die of the plurality of NOR memory dies and a respective portion of each volatile memory die of the plurality of volatile memory dies with the logic die, and
obtaining the one or more model parameters is in accordance with the plurality of vias.

17. The memory system of claim 12, wherein:
the plurality of NOR memory dies comprise NOR memory cells, and
the plurality of volatile memory dies comprise volatile memory cells.

18. The memory system of claim 17, wherein each NOR memory cell of the plurality of NOR memory dies comprises a first dielectric material, a second dielectric material, and a charge trapping layer between the first dielectric material and the second dielectric material.

19. The memory system of claim 18, wherein each NOR memory cell of the plurality of NOR memory dies stores a first bit at a first end of the charge trapping layer in accordance with trapping a first plurality of electrons at the first end of the charge trapping layer, and stores a second bit at a second end of the charge trapping layer in accordance with trapping a second plurality of electrons at the second end of the charge trapping layer.

20. A method for operating a memory system, comprising:
receiving, at a logic die of a stack of memory dies, a plurality of access commands directed to one or more model parameters associated with an artificial intelligence (AI) model, wherein the AI model is operated by processing circuitry coupled with the stack of memory dies, and wherein the stack of memory dies comprises a plurality of NOR memory dies and a plurality of volatile memory dies;
obtaining, at the logic die, the one or more model parameters from the plurality of NOR memory dies in accordance with receiving the plurality of access commands; and
transmitting, from the logic die, the one or more model parameters to the processing circuitry in response to obtaining the one or more model parameters from the plurality of NOR memory dies.

21. The method of claim 20, further comprising:
writing, by the logic die, the one or more model parameters to the plurality of volatile memory dies as part of a training operation for the AI model at the processing circuitry, wherein the one or more model parameters are generated in accordance with the training operation.

22. The method of claim 20, further comprising:
executing, by the processing circuitry, an AI inference operation using the one or more model parameters in accordance with transmitting the one or more model parameters from the logic die to the processing circuitry.

23. The method of claim 22, further comprising:
obtaining, at the logic die and from the processing circuitry, the one or more model parameters; and
writing, by the logic die to the plurality of NOR memory dies, the one or more model parameters, wherein executing the AI inference operation is in accordance with writing the one or more model parameters to the plurality of NOR memory dies.
